(19) United States
(12) Patent Application Publication
(10) Pub. No.: US 2015/0029644 A1
(43) Pub. Date: Jan. 29, 2015

(54) RF TRANSPARENT WOVEN MATERIAL FOR A WEARABLE DEVICE

(71) Applicant: ROSS ALCAZAR, Aurora, IL (US)

(72) Inventor: ROSS ALCAZAR, Aurora, IL (US)

(73) Assignee: Ross Dominique Diaz Alcazar, Aurora, IL (US)

(21) Appl. No.: 13/952,600

(22) Filed: Jul. 27, 2013

(51) Int. Cl. H05K 5/02

(52) U.S. Cl. CPC H05K 5/0247; H05K 5/0217
USPC 361/679.01

(57) ABSTRACT

An electronic device wirelessly connected to one or more portal devices for sensing user activities is provided. The electronic device includes an injected molded housing assembled with RF transparent woven material to be worn by the user and plurality of sensors positioned inside the housing for sensing activities of the user. The plurality of sensors for transmitting sensed activities wirelessly to the one or more portal devices. The injected molded housing assembled with RF transparent woven material providing a structural stability to the plurality of sensors and the sensor housing.

### CROSS-REFERENCE TO RELATED APPLICATION

This application claims the benefit of U.S. Provisional Application No. 61/804,172 filed on Mar. 21, 2013, which is hereby incorporated by reference in its entirety.

### BACKGROUND OF THE INVENTION

1. Field of the Invention

The present invention generally relates to a wearable wireless sensor device and more particularly relates to a wearable wireless sensor device woven with the RF transparent material.

2. Description of Related Art

Various wristbands are known in the art. Most of the wristband devices are flexible to fit around the wrist. The electronic circuitry should fit inside the straps of the wristband and should not compromise overall wristband flexibility. The flexibility of the electronic circuitry requires two-stage injection molding. The results of single injection molding of wristbands including flexible electrically conductive member are sub-standard. The results showed that injection molding of plastic material have caused deformity in the electric circuitry or have adverse affect on desired wristband properties.

Therefore, there is a need of a wearable device to provide structural stability to the electronic circuitry. Further, the wearable device should be injected molded with RF transparent woven material.

### SUMMARY OF THE INVENTION

In accordance with the teachings of the present invention, an electronic device assembled with RF transparent woven material connected to one or more portable device for sensing user activities is provided.

An object of the present invention to provide the electronic device having an injected molded housing assembled with RF transparent woven material and plurality of sensors positioned inside the housing for sensing user activities. The injection molded RF transparent woven material to provide structural stability to the sensors. Further, the plurality of sensors transmits sensed activities wirelessly to the one or more portal devices.

Another object of the present invention is to provide a wrist-mountable electronic device to be worn by the user on the wrist. The wrist-mountable electronic device includes plurality of sensors, sensor housing to retain said plurality of sensors and injection molded wristband having at least one end secured to the sensor housing. The injected molded wristband includes a flexible electrically conductive member being electrically connected through the at least one end to the sensor housing.

Another object of the present invention is to provide the electrically conductive member nipped in between the upper and lower faces of molding cavity of the injection molded wristband.

Another object of the present invention is to provide the wrist-mountable electronic device further includes in-built speakers, power source for producing audio and charging the battery, respectively.

These and other objects, features and advantages of the invention will become more fully apparent in the following detailed description, taken in conjunction with the accompanying drawings.

### BRIEF DESCRIPTION OF DRAWINGS

FIG. 1 illustrates a perspective view of an electronic device in an exemplary embodiment of the present invention; and

FIG. 2 illustrates a perspective view of a wrist-mountable electronic device in accordance with a preferred embodiment of the present invention.

### DETAILED DESCRIPTION OF DRAWINGS

While this technology is illustrated and described in a preferred embodiment, the wearable wireless sensor device may be produced in many different configurations, forms and materials. There is depicted in the drawings, and will herein be described in detail, as a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the technology described herein.

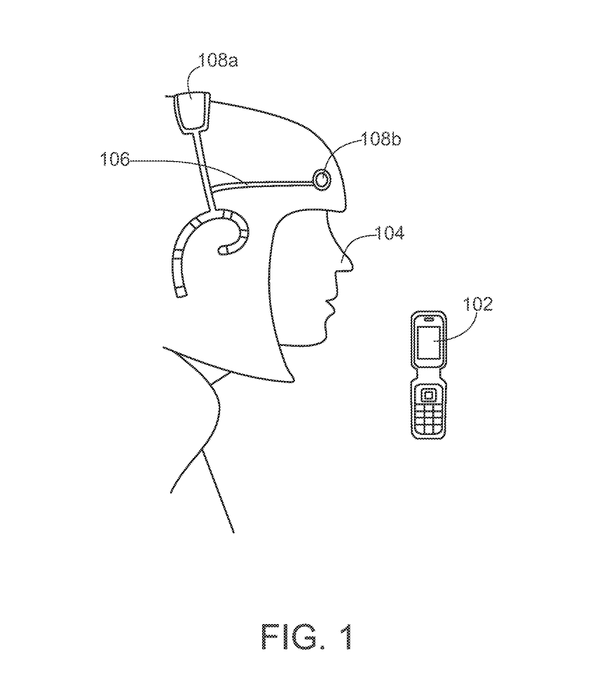

FIG. 1 illustrates a perspective view of an electronic device 100 in an exemplary embodiment of the present invention. The electronic device 100 is wirelessly connected to the one or more portal devices 102 for sensing user 104 activities. The electronic device 100 includes an injected molded housing 106 assembled with RF transparent woven material to be worn by the user 104 and plurality of sensors 108 such as 108a and 108b are positioned inside the housing 106 for sensing the user 104 activities. The plurality of sensors 108 then further transmits the sensed activities wirelessly to the one or more portal device 102. The injected molded RF transparent woven material coated housing 106 provides structural stability to the plurality of sensors 108. In a preferred embodiment of the present invention as shown in FIG. 1 the housing 106 is a headgear and the one or more portable device 102 is a mobile phone.

Example of housing 106 includes but not limited to headphones, wristband, wristwatches etc. Example of portable device 102 includes but not limited to IPAD, Laptops, tablets etc. However, it will be readily apparent to those skilled in the art that many variations of the housing and portable device may be envisioned without deviating from the scope of the present invention.

In a preferred embodiment of the present invention, the RF transparent woven material is either a glass fiber or a carbon fiber. In another preferred embodiment of the present invention, the electronic device 100 further includes a power source (not shown in Figures) to power the plurality of sensors 108 and one or more speakers (not shown in Figures) to produce sound.

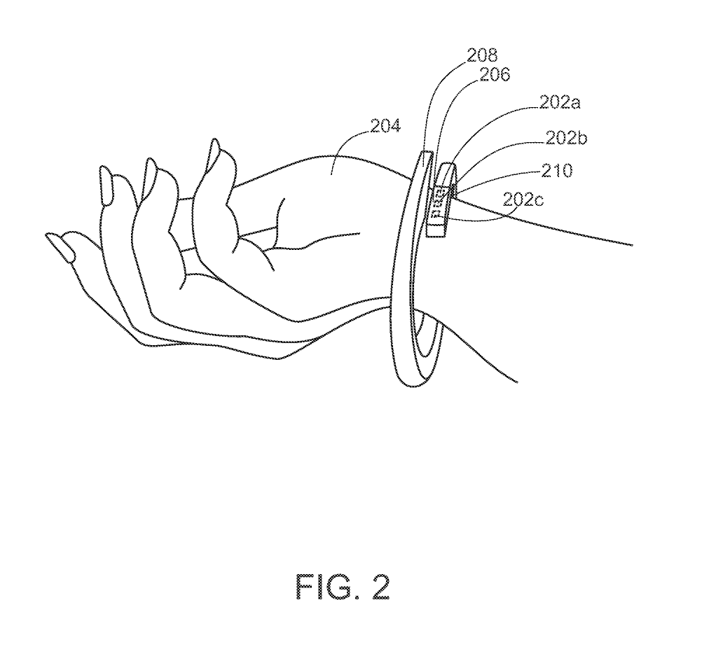

FIG. 2 illustrates a perspective view of a wrist-mountable electronic device 200, in accordance with another preferred embodiment of the present invention. The wrist-mountable electronic device 200 is wirelessly connected to one or more portable devices (not shown in FIG. 2). The wrist-mountable electronic device 200 includes plurality of sensors 202 such as 202a, 202b and 202c for sensing the activities of the user 204 and further transmitting the sensed activities to the one or more portable devices (not shown in FIG. 2).

The wrist-mountable electronic device 200 further includes a sensor housing 206 for retaining the plurality of sensors 202 and is further configured to be worn on the user's wrist. The wrist-mountable electronic device 200 further includes an injected molded wristband 208 coated with RF transparent woven material having at least one end 210 secured to the sensor housing 206. The injected molded wristband 208 further includes a flexible electrically conductive member 212 electrically connected to the sensor housing 206.

In a preferred embodiment of the present invention, the flexible electrically conductive member 212 is nipped in between the upper and lower faces of molding cavity of the injected molded wristband 208.

The present invention offers various advantages. The RF transparent woven material injected molded housing provides structural stability to the sensors and produce greater results without any deformity to the electronic device.

The foregoing discussion discloses and describes merely exemplary embodiments of the present invention. One skilled in the art will readily recognize from such discussion and from the accompanying drawings that various changes, modifications and variations can be made therein without departing from the spirit and scope of the invention.

1. An electronic device wirelessly connected to one or more portal devices for sensing user activities, said electronic device comprising:
an injected molded housing assembled with RF transparent woven material to be worn by said user; and
plurality of sensors positioned inside said housing for sensing activities of the user, said plurality of sensors for transmitting sensed activities wirelessly to said one or more portal devices; and
wherein said injected molded housing assembled with RF transparent woven material providing a structural stability to said plurality of sensors.

2. The electronic device according to claim 1 wherein said injected molded housing assembled with RF transparent woven material is a wristband.

3. The electronic device according to claim 1 wherein said injected molded housing assembled with RF transparent woven material is a headgear.

4. The electronic device according to claim 1 wherein said injected molded housing assembled with RF transparent woven material is a wristwatch.

5. The electronic device according to claim 1 wherein said RF transparent woven material comprising either a glass fiber or a carbon fiber.

6. The electronic device according to claim 1 wherein said portable device is either a smartphone or a laptop or a tablet.

7. The electronic device according to claim 1 wherein said electronic device further comprising a power source to power said plurality of sensors.

8. The electronic device according to claim 1 wherein said electronic device further comprising one or more speakers to produce sound.

9. A wrist-mountable electronic device wirelessly connected to one or more portable devices for sensing user activities, said electronic device comprising:
plurality of sensors for sensing user activities and further transmitting sensed activities wirelessly to said one or more portal devices;
a sensor housing for retaining said plurality of sensors, said sensor housing configured to be worn on said user's wrist; and
an injected molded wristband assembled with RF transparent woven material having at least one end secured to said sensor housing; said injected molded wristband further comprising a flexible electrically conductive member being electrically connected to said sensor housing, wherein said injected molded wristband assembled with RF transparent woven material providing a structural stability to said sensor housing and said plurality of sensors.

10. The wrist-mountable electronic device according to claim 9 wherein said electrically conductive member nipped in between upper and lower faces of molding cavity of said injected molded wristband.

11. The wrist-mountable electronic device according to claim 9 wherein said RF transparent woven material comprising either a glass fiber or a carbon fiber.

12. The wrist-mountable electronic device according to claim 9 wherein said portable device is either a smartphone or a laptop or a tablet.

13. The wrist-mountable electronic device according to claim 9 wherein said electronic device further comprising a power source to power said plurality of sensors.

14. The wrist-mountable electronic device according to claim 9 wherein said electronic device further comprising one or more speakers to produce sound.
